(19) United States
(12) Patent Application Publication
(10) Pub. No.: US 2026/0344354 A1
(43) Pub. Date: Oct. 29, 2026

(54) SUSCEPTOR

(71) Applicant: NGK CORPORATION, Nagoya-shi (JP)

(72) Inventor: Daisuke TSUNEKAWA, Nagoya-shi (JP)

(21) Appl. No.: 19/697,920

(22) Filed: Jun. 4, 2026

Related U.S. Application Data
(63) Continuation of application No. PCT/JP2025/035407, filed on Oct. 6, 2025.

(30) Foreign Application Priority Data
Nov. 5, 2024 (JP) 2024-193518

(51) Int. Cl. H10P 72/72; H02N 13/00

(52) U.S. Cl. CPC H10P 72/72; H02N 13/00

(57) ABSTRACT

The susceptor includes a ceramic plate having a first principal surface and a second principal surface. A first support wall which extends in a circumferential direction of the ceramic plate is formed on the first principal surface of the ceramic plate. An electrostatic chuck electrode configured to attract the wafer is built in the ceramic plate. The electrostatic chuck electrode includes: a positive electrode and a negative electrode. The positive electrode includes a plurality of first positive electrode portions which overlap part of a ring-shaped region of the first principal surface, the first support wall being formed on the ring-shaped region. The negative electrode includes a plurality of first negative electrode portions which overlap part of the ring-shaped region. The plurality of first positive electrode portions and the plurality of first negative electrode portions are alternately arranged in the circumferential direction of the ceramic plate.

### CROSS-REFERENCE TO RELATED APPLICATIONS

This application is a continuation application of PCT/JP 2025/035407, filed on Oct. 6, 2025, which claims the benefit of priority of Japanese Patent Application No. 2024-193518, filed on Nov. 5, 2024, the entire contents of which are incorporated herein by reference.

### TECHNICAL FIELD

The present disclosure relates to a susceptor.

### Background Art

In a semiconductor manufacturing apparatus, a

susceptor is used as a base for supporting a wafer when processing such as film forming and etching is performed on the wafer. The susceptor includes a sheet-shaped ceramic plate. One of principal surfaces of the ceramic plate includes a wafer supporting surface for supporting the wafer. Some susceptors include a support wall that is formed from a ring-shaped protrusion on the wafer supporting surface. When the wafer is placed on the support wall, a space surrounded by the support wall is defined between the wafer and the ceramic plate. Into this space, for example, a gas for enabling efficient thermal conduction between the wafer and the ceramic plate is supplied.

For example, in a process of forming a semiconductor thin film, it is required that the wafer be held on the wafer supporting surface so as not to be moved. Thus, the susceptor is required to have an electrostatic attraction function for attracting the wafer onto the wafer supporting surface with an electrostatic force. The electrostatic attraction includes monopolar electrostatic attraction and bipolar electrostatic attraction. The monopolar electrostatic attraction uses an electrostatic chuck electrode for generating an attraction force on the wafer supporting surface, which is built in the ceramic plate. The bipolar electrostatic attraction uses two kinds of electrostatic chuck electrodes, that is, a positive electrode and a negative electrode, which are built in the ceramic plate while being separated from each other.

In the bipolar electrostatic attraction, an attraction force is generated by applying a voltage between the positive electrode and the negative electrode. Reference is now made to FIG. 14. A positive electrode 100 and a negative electrode 101 are each formed in, for example, a semi-circular shape (see, for example, Japanese Patent Application Laid-open No. 2005-294648).

### SUMMARY OF INVENTION

In the case of the bipolar electrostatic attraction, when an electrical polarity difference is generated in the ceramic plate between an area in which the positive electrode is embedded and an area in which the negative electrode is embedded, a difference is generated between an attraction force generated in a region of the wafer supporting surface under which the positive electrode is embedded and an attraction force generated in a region of the wafer supporting surface under which the negative electrode is embedded. As a result, the wafer supporting surface includes a region with a strong attraction force for the wafer and a region with a weak attraction force for the wafer. In the case of the ceramic plate with the support wall formed thereon, the wafer is placed on the support wall and thus the support wall is a portion to be in direct contact with the wafer. Accordingly, the attraction force generated from the support wall significantly affects the attraction of the wafer and is thus particularly important. However, when the positive electrode 100 and the negative electrode 101, each having a semi-circular shape as illustrated in FIG. 14, are built in a ceramic plate 102, a support wall 103 is divided into two parts, that is, a portion 104 with a high attraction force and a portion 105 with a low attraction force. As a result, there is a fear that the attraction of the wafer caused by the support wall 103 becomes non-uniform and the wafer cannot be stably held on the wafer supporting surface.

In order to stably hold the wafer on the wafer supporting surface, non-uniformity in the attraction force generated from the support wall, on which the wafer is to be placed, is required to be suppressed. One object of the present disclosure is to provide a susceptor capable of stably holding a wafer on a wafer supporting surface.

According to at least one embodiment of the present disclosure, there is provided a susceptor including a ceramic plate having a first principal surface and a second principal surface being a pair of principal surfaces which are positioned apart from each other in a thickness direction of the ceramic plate. In a susceptor according to a first aspect of the present disclosure, a first support wall which extends in a circumferential direction of the ceramic plate is formed on the first principal surface of the ceramic plate. A wafer is to be placed on the first support wall. Further, an electrostatic chuck electrode configured to attract the wafer is built in the ceramic plate. The electrostatic chuck electrode includes: a positive electrode to which a positive voltage is to be applied; and a negative electrode to which a negative voltage is to be applied. The positive electrode includes a first positive electrode portion which overlaps part of a ring-shaped region of the first principal surface when viewed in a direction orthogonal to the first principal surface, the first support wall being formed on the ring-shaped region. The negative electrode includes a first negative electrode portion which overlaps part of the ring-shaped region when viewed in the direction orthogonal to the first principal surface. A plurality of first positive electrode portions and a plurality of first negative electrode portions are alternately arranged in the circumferential direction of the ceramic plate.

According to the at least one embodiment of the present disclosure, the susceptor capable of stably holding the wafer on the first principal surface of the ceramic plate, on which the wafer is to be supported, can be provided.

### BRIEF DESCRIPTION OF DRAWINGS

FIG. 1 is a plan view of a susceptor according to at least one embodiment of the present disclosure.

FIG. 2 is a schematic sectional view of the susceptor illustrated in FIG. 1, taken along a vertical plane including the line II-II of FIG. 1.

FIG. 3 is a schematic sectional view of a susceptor according to a modification example of the present disclosure.

FIG. 4 is a plan view of a susceptor according to a modification example of the present disclosure.

FIG. 5 is a schematic sectional view of the susceptor illustrated in FIG. 4, taken along a vertical plane including the line V-V of FIG. 4.

FIG. 6 is a view for illustrating a first example of electrode shapes of a positive electrode and a negative electrode that are built in a ceramic plate of the susceptor illustrated in FIG. 1.

FIG. 7 is a view for illustrating a second example of the electrode shapes of the positive electrode and the negative electrode that are built in the ceramic plate of the susceptor illustrated in FIG. 1.

FIG. 8 is a view for illustrating a third example of the electrode shapes of the positive electrode and the negative electrode that are built in the ceramic plate of the susceptor illustrated in FIG. 1.

FIG. 9 is a view for illustrating a fourth example of the electrode shapes of the positive electrode and the negative electrode that are built in the ceramic plate of the susceptor illustrated in FIG. 1.

FIG. 10 is a plan view of a susceptor according to a modification example of the present disclosure.

FIG. 11 is a schematic sectional view of the susceptor illustrated in FIG. 10, taken along a vertical plane including the line XI-XI of FIG. 10.

FIG. 12 is a plan view of a susceptor according to a modification example of the present disclosure.

FIG. 13 is a view for illustrating electrode shapes of a positive electrode and a negative electrode that are built in a ceramic plate of the susceptor illustrated in FIG. 12.

FIG. 14 is a view for illustrating a related-art example of electrode shapes of a positive electrode and a negative electrode that are built in a ceramic plate of a susceptor.

### DESCRIPTION OF EMBODIMENTS

### Outline of Embodiments

First, aspects of carrying out a susceptor according to the present disclosure are listed and described.

According to a first aspect of the present disclosure, there is provided a susceptor including a ceramic plate having a first principal surface and a second principal surface being a pair of principal surfaces which are positioned apart from each other in a thickness direction of the ceramic plate. In the susceptor according to the first aspect, a first support wall which extends in a circumferential direction of the ceramic plate is formed on the first principal surface of the ceramic plate. A wafer is to be placed on the first support wall. Further, an electrostatic chuck electrode configured to attract the wafer is built in the ceramic plate. The electrostatic chuck electrode includes: a positive electrode to which a positive voltage is to be applied; and a negative electrode to which a negative voltage is to be applied. The positive electrode includes a plurality of first positive electrode portions which overlap part of a ring-shaped region of the first principal surface when viewed in a direction orthogonal to the first principal surface, the first support wall being formed on the ring-shaped region. The negative electrode includes a plurality of first negative electrode portions which overlap part of the ring-shaped region when viewed in the direction orthogonal to the first principal surface. The plurality of first positive electrode portions and the plurality of first negative electrode portions are alternately arranged in the circumferential direction of the ceramic plate.

With the susceptor according to the first aspect, the plurality of first positive electrode portions and the plurality of first negative electrode portions are alternately arranged in the circumferential direction of the ceramic plate below the first support wall, on which the wafer is to be placed, inside the ceramic plate. The term “below” refers to a direction from the first principal surface toward the second principal surface in the thickness direction of the ceramic plate. Thus, when a voltage is applied between the positive electrode and the negative electrode, portions with a high attraction force and portions with a low attraction force are alternately formed in a well-balanced manner in the first support wall. Accordingly, with the susceptor according to the first aspect, non-uniformity in the attraction of the wafer caused by the first support wall is suppressed. Thus, the wafer can be stably held on the first principal surface.

As a susceptor according to a second aspect of the present disclosure, the susceptor according to the first aspect may be configured such that: the positive electrode and the negative electrode of the electrostatic chuck electrode are a single positive electrode and a single negative electrode, respectively; the positive electrode includes: the plurality of first positive electrode portions arranged apart from each other in the circumferential direction of the ceramic plate; and a second positive electrode portion which is continuous with the plurality of first positive electrode portions, and to which a power feeding terminal for a positive electrode is to be electrically connected; and the negative electrode includes: the plurality of first negative electrode portions arranged apart from each other in the circumferential direction of the ceramic plate; and a second negative electrode portion which is continuous with the plurality of first negative electrode portions, and to which a power feeding terminal for a negative electrode is to be electrically connected.

In the susceptor according to the second aspect, only one positive electrode and only one negative electrode are built in the ceramic plate as the electrostatic chuck electrode. The plurality of first positive electrode portions and the plurality of first negative electrode portions are alternately arranged in the circumferential direction of the ceramic plate below the first support wall by appropriately designing electrode shapes of the positive electrode and the negative electrode. Accordingly, only one power feeding terminal for a positive electrode and only one power feeding terminal for a negative electrode are required to be provided to the ceramic plate. Thus, with the susceptor according to the second aspect, a structure of the ceramic plate can be simplified. Further, for example, when a resistance heating element is built in the ceramic plate, the resistance heating element is required to be arranged while avoiding the power feeding terminals. When a plurality of positive electrodes and a plurality of negative electrodes are built in the ceramic plate, a plurality of power feeding terminals for a positive electrode and a plurality of power feeding terminals for a negative electrode are required to be provided in the ceramic plate accordingly. As a result, a large number of cool spots, which are formed as a result of arranging the resistance heating element while avoiding the power feeding elements, are formed in the ceramic plate correspondingly. When a large number of cool spots are formed in the ceramic plate, non-uniformity in temperature is liable to occur in the ceramic plate at the time of heating of the ceramic plate with the resistance heating element, affecting thermal uniformity of the ceramic plate. Meanwhile, in the susceptor according to the second aspect, only one positive electrode and only one negative electrode are built in the ceramic plate, and only one power feeding terminal for a positive electrode and only one power feeding terminal for a negative electrode are provided to the ceramic plate. Thus, the number of cool spots formed in the ceramic plate can be reduced. Accordingly, in the susceptor according to the second aspect, the thermal uniformity of the ceramic plate can be improved.

As a susceptor according to a third aspect of the present disclosure, the susceptor according to the second aspect may be configured such that, when viewed in the direction orthogonal to the first principal surface, the second positive electrode portion and the second negative electrode portion are arranged in a center of the ceramic plate, one of the plurality of first positive electrode portions or the plurality of first negative electrode portions extend from an outer peripheral edge of the ceramic plate toward the center of the ceramic plate, and another one of the plurality of first positive electrode portions or the plurality of first negative electrode portions extend from the center of the ceramic plate toward the outer peripheral edge of the ceramic plate.

In the susceptor according to the third aspect, the plurality of first positive electrode portions and the plurality of first negative electrode portions are alternately arranged in the circumferential direction of the ceramic plate, not only below the first support wall but also on an inner side of the first support wall, inside the ceramic plate. Thus, when a voltage is applied between the positive electrode and the negative electrode, portions with a high attraction force and portions with a low attraction force are alternately formed in a well-balanced manner over substantially the entire first principal surface. Accordingly, with the susceptor according to the third aspect, non-uniformity in the attraction of the wafer caused by the first principal surface is suppressed. Thus, the wafer can be more stably held on the first principal surface.

As a susceptor according to a fourth aspect of the present disclosure, the susceptor according to the second aspect may be configured such that: when viewed in the direction orthogonal to the first principal surface, the second positive electrode portion and the second negative electrode portion are arranged in a center of the ceramic plate; the positive electrode includes a plurality of third positive electrode portions which are arranged between the plurality of first positive electrode portions and the second positive electrode portion so as to be apart from each other in the circumferential direction of the ceramic plate, the plurality of third positive electrode portions being continuous with the plurality of first positive electrode portions and the second positive electrode portion; and the negative electrode includes a plurality of third negative electrode portions which are arranged alternately with the plurality of third positive electrode portions in the circumferential direction of the ceramic plate between the plurality of first negative electrode portions and the second negative electrode portion, the plurality of third negative electrodes being continuous with the plurality of first negative electrode portions and the second negative electrode portion.

In the susceptor according to the fourth aspect, the plurality of third positive electrode portions and the plurality of third negative electrode portions are alternately arranged in the circumferential direction of the ceramic plate, not only below the first support wall but also on the inner side of the first support wall, inside the ceramic plate. Thus, when a voltage is applied between the positive electrode and the negative electrode, portions with a high attraction force and portions with a low attraction force are alternately formed in a well-balanced manner over substantially the entire first principal surface. Accordingly, with the susceptor according to the fourth aspect, non-uniformity in the attraction of the wafer caused by the first principal surface is suppressed. Thus, the wafer can be more stably held on the first principal surface.

As a susceptor according to a fifth aspect of the present disclosure, the susceptor according to any one of the first aspect to the fourth aspect may be configured such that a resistance heating element configured to generate heat through energization is built in the ceramic plate.

With the susceptor according to the fifth aspect, the ceramic plate can be heated with the resistance heating element, and the wafer can be heated via the first principal surface. At the time of heating, the wafer is attracted to the first principal surface under a state in which non-uniformity in the attraction force is suppressed. Thus, the wafer can be uniformly heated.

As a susceptor according to a sixth aspect of the present disclosure, the susceptor according to any one of the first aspect to the fifth aspect may be configured such that: at least one of a set of a plurality of support protrusions or at least one second support wall extending in the circumferential direction of the ceramic plate is formed on a region of the first principal surface of the ceramic plate, the region being surrounded by the first support wall; and distal ends of the support protrusions and a distal end of the second support wall are positioned at the same height in the thickness direction of the ceramic plate as a height at which a distal end of the first support wall is positioned.

With the susceptor according to the sixth aspect, the wafer is supported on the first principal surface under a state in which the wafer is in contact not only with the distal end of the first support wall but also with at least one of a set of the distal ends of the plurality of support protrusions or the distal end of the second support wall. Accordingly, with the susceptor according to the sixth aspect, the wafer is more stably supported on the first principal surface. Further, when portions with a high attraction force and portions with a low attraction force are alternately formed in a well-balanced manner over substantially the entire first principal surface by alternately arranging the plurality of first positive electrode portions and the plurality of first negative electrode portions or alternately arranging the plurality of third positive electrode portions and the plurality of third negative electrode portions in the circumferential direction of the ceramic plate on the inner side of the first support wall, non-uniformity in the attraction of the wafer caused by at least one of the plurality of support protrusions or the second support wall is suppressed. Accordingly, the wafer can be stably held on the first principal surface.

As a susceptor according to a seventh aspect of the present disclosure, the susceptor according to the sixth aspect may be configured such that a proportion of an area of the first support wall that is to be in contact with the wafer in a total area of portions of the ceramic plate that are to be in contact with the wafer is 40% or more.

With the susceptor according to the seventh aspect, the first support wall and at least one of the plurality of support protrusions or the second support wall are in contact with the wafer that is supported on the first principal surface. Among the above-mentioned portions, the first support wall is a main portion being in contact with the wafer. As a result, the wafer can be more stably held on the first principal surface.

As a susceptor according to an eighth aspect of the present disclosure, the susceptor according to any one of the first aspect to the seventh aspect may be configured such that the first support wall is formed in a ring shape so as to extend over an entire circumference in the circumferential direction of the ceramic plate.

With the susceptor according to the eighth aspect, when the wafer is placed on the first support wall, a sealed space surrounded by the first support wall is defined between the wafer and the ceramic plate. With the susceptor according to the eighth aspect, the wafer can be efficiently and uniformly heated by supplying, for example, a gas for enabling efficient thermal conduction between the wafer and the ceramic plate into the sealed space.

As a susceptor according to a ninth aspect of the present disclosure, the susceptor according to any one of the first aspect to the seventh aspect may be configured such that the first support wall is formed from a plurality of ridge portions which extend in the circumferential direction of the ceramic plate and are arranged apart from each other in the circumferential direction of the ceramic plate.

With the susceptor according to the ninth aspect, when the wafer is placed on the first support wall, a space surrounded by the first support wall is defined between the wafer and the ceramic plate. With the susceptor according to the ninth aspect, the wafer can be uniformly heated by supplying, for example, a gas for enabling efficient thermal conduction between the wafer and the ceramic plate into the space. Further, when, for example, processing of film forming is performed on the wafer, formation of an abnormal film on the outer peripheral edge of the second principal surface of the wafer can be suppressed by discharging the gas from the space to an outside of the first support wall through voids between adjacent ridge portions.

As a susceptor according to a tenth aspect of the present disclosure, the susceptor according to any one of the first aspect to the ninth aspect may be configured such that the wafer is a semiconductor substrate, and the susceptor is used for attraction of the semiconductor substrate.

### Specific Examples of Embodiment

Next, at least one specific embodiment of the susceptor according to the present disclosure is described with reference to the drawings. Throughout the drawings, parts that are the same as or correspond to each other are denoted by the same reference numeral.

The susceptor according to the present disclosure is used as a base made of ceramic for supporting the wafer in a semiconductor manufacturing apparatus. An electrostatic chuck for a semiconductor etching apparatus and a ceramic heater for a semiconductor film forming apparatus are given as examples of the susceptor. A chemical vapor deposition (CVD) apparatus and a physical vapor deposition (PVD) apparatus are given as examples of the semiconductor film forming apparatus.

A semiconductor substrate and a glass substrate are given as examples of the wafer. The wafer is preferably a semiconductor substrate. Various semiconductors such as silicon (Si), silicon carbide (SiC), and gallium nitride (GaN) are given as the semiconductor.

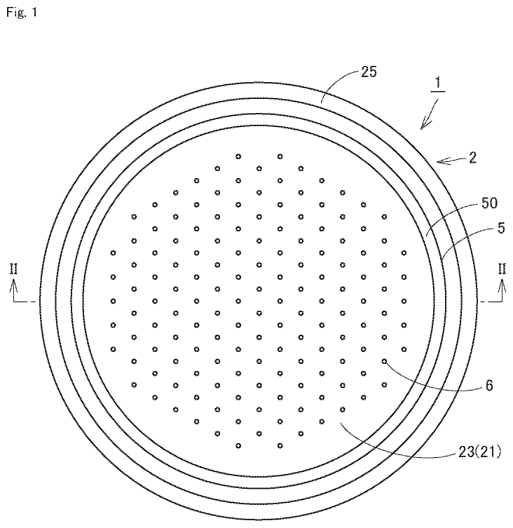

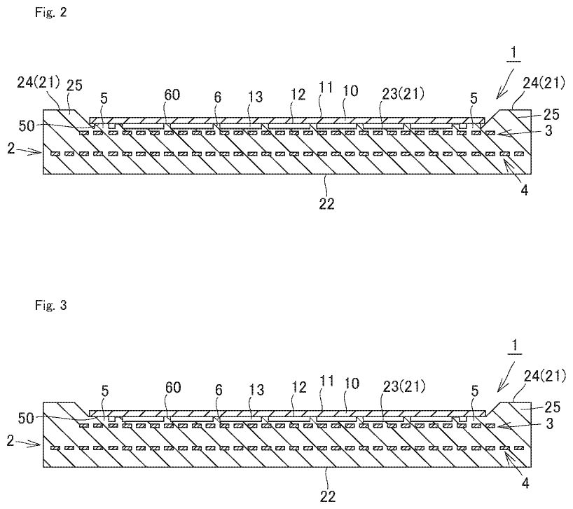

FIG. 1 is a plan view of a susceptor 1 according to at least one embodiment of the present disclosure. FIG. 2 is a schematic sectional view of the susceptor 1 illustrated in FIG. 1.

The susceptor 1 includes: a ceramic plate 2 formed in a sheet-like shape; and an electrostatic chuck electrode 3 built in the ceramic plate 2. The susceptor 1 may further include a resistance heating element 4, which is built in the ceramic plate 2. Inside the ceramic plate 2, for example, the electrostatic chuck electrode 3 is provided at a position close to a first principal surface 21 in a thickness direction of the ceramic plate 2, and the resistance heating element 4 is provided at a position farther away from the first principal surface 21 than the electrostatic chuck electrode 3 in the thickness direction of the ceramic plate 2.

### Description of Ceramic Plate

The ceramic plate 2 is formed from, for example, a sintered body of ceramic. Aluminum nitride (AlN), aluminum oxide (Al₂O₃), silicon carbide (SiC), and silicon nitride (Si₃N₄) are given as examples of the ceramic. The ceramic plate 2 is only required to be formed with one of the above-mentioned ceramics as a main component, and may contain a component originating from a sintering aid, or the like. A rare-earth metal oxide is given as an example of the sintering aid. The term “main component” means that ceramic is contained at 50% or higher by mass, preferably at 70% or higher by mass.

Reference is made to FIG. 1 and FIG. 2. The ceramic plate 2 is formed from, for example, a circular plate having a circular shape when viewed in a direction orthogonal to the first principal surface 21. A size of the ceramic plate 2 is, for example, 200 mm or more and 400 mm or less in diameter, and 5 mm or more and 30 mm or less in thickness.

The ceramic plate 2 has the first principal surface 21 and a second principal surface 22, which are a pair of principal surfaces positioned apart from each other in the thickness direction. The first principal surface 21 includes a wafer supporting surface 23 for supporting a wafer 10. The first principal surface 21 and the second principal surface 22 are parallel or substantially parallel to each other. The phrase “substantially parallel” includes a case in which one is tilted with respect to the other to a certain degree, a case in which at least one is somewhat warped and is not flat, and the like.

An area of the ceramic plate 2, extending inward from an outer peripheral edge of the ceramic plate 2 on the first principal surface 21 side and having a predetermined width, may rise over an entire circumference in a circumferential direction of the ceramic plate 2. This rise forms an outer wall 25 at the outer peripheral edge of the first principal surface 21. A region of the first principal surface 21 that is surrounded by the outer wall 25 is the wafer supporting surface 23. The outer wall 25 has an upper surface 24 having an annular shape, which is positioned above the wafer supporting surface 23 in the thickness direction of the ceramic plate 2. The upper surface 24 of the outer wall 25 is parallel or substantially parallel to the wafer supporting surface 23. The wafer supporting surface 23 and the upper surface 24 of the outer wall 25 form the first principal surface 21.

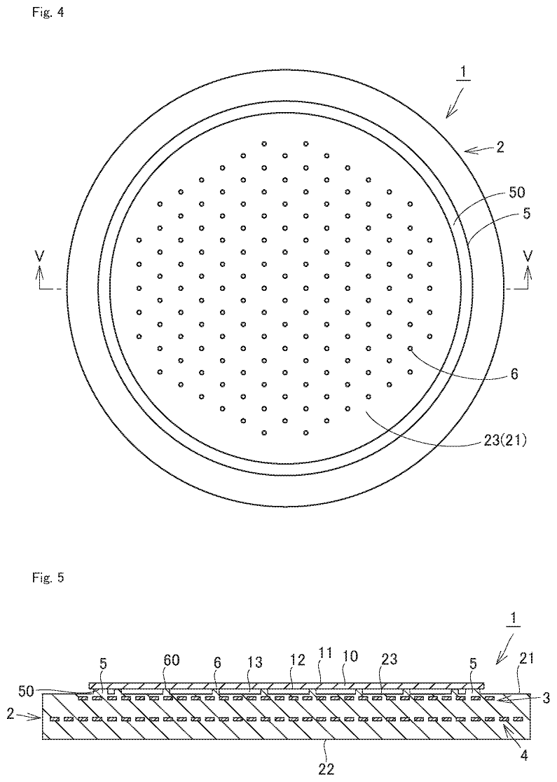

As illustrated in FIG. 4 and FIG. 5, the outer wall 25 is not always required to be formed at the outer peripheral edge of the first principal surface 21 of the ceramic plate 2. The first principal surface 21 of the ceramic plate 2 may be a flat or substantially flat surface.

Reference is made to FIG. 1 and FIG. 2. A first support wall 5 protruding from the wafer supporting surface 23 of the first principal surface 21 is formed on the ceramic plate 2. The first support wall 5 extends in the circumferential direction of the ceramic plate 2. That is, the first support wall 5 extends in parallel to the outer peripheral edge of the ceramic plate 2 at the outer peripheral edge of the ceramic plate 2 or on an inner side of the outer peripheral edge.

The first support wall 5 can be formed from a ring-shaped protrusion extending over the entire circumference in the circumferential direction of the ceramic plate 2, that is, a ring-shaped protrusion extending in parallel to the outer peripheral edge of the ceramic plate 2 over the entire circumference in the outer peripheral edge of the ceramic plate 2. In the at least one embodiment, the first support wall 5 is formed from an annular protrusion.

On the ceramic plate 2, the first support wall 5 is a main portion on which the wafer 10 is to be placed. When the wafer 10 is placed on the first support wall 5, the wafer 10 is supported on the wafer supporting surface 23 of the ceramic plate 2. A distal end surface 50 of the first support wall 5 is in contact with a second principal surface 12 out of a pair of principal surfaces 11 and 12 of the wafer 10, which is on a side opposed to the wafer supporting surface 23. When the first support wall 5 is formed from a ring-shaped protrusion, a space 13 surrounded by the first support wall 5 is defined between the wafer 10 and the ceramic plate 2. Into this space 13, a gas high in thermal conductivity, for example, a helium gas, is supplied so as to achieve, for example, efficient thermal conduction between the wafer 10 and the ceramic plate 2.

A sectional shape of the first support wall 5 perpendicular to the wafer supporting surface 23 is, for example, rectangular or trapezoidal. The end surface (distal end surface) 50 of the first support wall 5, which protrudes from the wafer supporting surface 23, may be a flat or substantially flat surface. A height of the first support wall 5, that is, a length by which the first support wall 5 protrudes from the wafer supporting surface 23 (a vertical distance between the distal end surface 50 of the first support wall 5 and the wafer supporting surface 23) is from about several μm to about several hundred μm. Further, a width of the first support wall 5, that is, a distance between an inner peripheral surface and an outer peripheral surface of the first support wall 5 is from about 1 mm to about 50 mm.

As illustrated in FIG. 3, the first support wall 5 may be formed integrally with the outer wall 25 so as to be continuous therewith.

Reference is made to FIG. 1 and FIG. 2. A plurality of support protrusions 6 protruding from the wafer supporting surface 23 of the first principal surface 21 may be formed on the ceramic plate 2. The plurality of support protrusions 6 are formed on a region of the wafer supporting surface 23 that is surrounded by the first support wall 5.

A sectional shape of each of the support protrusions 6 that is perpendicular to the wafer supporting surface 23 is, for example, rectangular or trapezoidal. An end surface (distal end surface) 60 of each of the support protrusions 6, which protrudes from the wafer supporting surface 23, may be a flat or substantially flat surface. A sectional shape of each of the support protrusions 6 that is parallel to the wafer supporting surface 23 is, for example, circular or rectangular. The support protrusion 6 may be formed from a columnar or truncated conical protrusion.

A height of the support protrusions 6, that is, a length by which the support protrusions 6 protrude from the wafer supporting surface 23 (a vertical distance between the distal end surfaces 60 of the support protrusions 6 and the wafer supporting surface 23) is from about several μm to about several hundred μm. Further, the support protrusions 6 each have a diameter of from about 0.5 mm to about 5 mm.

The distal end surfaces 60 being distal ends of the support protrusions 6 are positioned at the same height in the thickness direction of the ceramic plate 2 as a height at which the distal end surface 50 being a distal end of the first support wall 5 is positioned. The phrase “positioned at the same height” also includes being “positioned at substantially the same height,” and hence also includes being positioned at a slightly different position due to a manufacturing variation or the like. In the at least one embodiment, the length by which the first support wall 5 protrudes from the wafer supporting surface 23, which defines the height of the first support wall 5, and the length by which the support protrusions 6 protrude from the wafer supporting surface 23, which defines the height of the support protrusions 6, are the same or substantially the same.

When the wafer 10 is to be supported on the wafer supporting surface 23 of the ceramic plate 2, the wafer 10 is placed in contact not only with the distal end surface 50 of the first support wall 5 but also with the distal end surfaces 60 of the plurality of support protrusions 6. The distal end surfaces 60 of the plurality of support protrusions 6 are in contact with the second principal surface 12 of the wafer 10, and the wafer 10 is supported by the plurality of support protrusions 6 from below.

The plurality of support protrusions 6 can be arranged at equal intervals on the region of the wafer supporting surface 23 that is surrounded by the first support wall 5. When the plurality of support protrusions 6 are evenly arranged, the entirety of the wafer 10 can be supported evenly on the wafer supporting surface 23.

In the at least one embodiment, portions of the ceramic plate 2 to be in contact with the wafer 10 are the distal end surface 50 of the first support wall 5 and the distal end surfaces 60 of the plurality of support protrusions 6. A proportion of the first support wall 5 in a total area of the portions to be in contact with the wafer 10, that is, a proportion of an area of the distal end surface 50 of the first support wall 5 in the total area obtained by adding up the area of the distal end surface 50 of the first support wall 5 and areas of the distal end surfaces 60 of the plurality of support protrusions 6 is preferably 40% or more. When only the first support wall 5 and the plurality of support protrusions 6 are formed on the wafer supporting surface 23 as in the at least one embodiment, the proportion is more preferably 45% or more, still more preferably 50% or more. Further, the proportion of the area of the distal end surface 50 of the first support wall 5 in the total area obtained by adding up the area of the distal end surface 50 of the first support wall 5 and the areas of the distal end surfaces 60 of the plurality of support protrusions 6 is, for example, 95% or less, preferably 90% or less. When the proportion of the area of the distal end surface 50 of the first support wall 5 falls within a range of 40% or more and 95% or less, a sufficient attraction force can be exerted from the first support wall 5 on the wafer 10. Thus, the wafer 10 is firmly attracted to the wafer supporting surface 23. Further, when the wafer 10 is removed from the wafer supporting surface 23, the wafer 10 can be released from the first support wall 5 with high responsiveness.

Although not shown, various holes may be formed in the ceramic plate 2 so as to pass therethrough in the thickness direction of the ceramic plate 2. For example, a hole for inserting a lift pin which is used to lift up the wafer from the ceramic plate 2 after processing such as film forming is finished may be formed in the ceramic plate 2. Further, a hole for supplying a gas into the space 13 surrounded by the first support wall 5 between the wafer 10 and the ceramic plate 2 may be formed in the ceramic plate 2. Further, a hole for inserting a thermocouple that detects a temperature of the ceramic plate 2 may be formed in the ceramic plate 2.

### Description of Electrostatic Chuck Electrode

Reference is made to FIG. 2. The electrostatic chuck electrode 3 is provided between the first principal surface 21 and the second principal surface 22 of the ceramic plate 2 so as to spread in a planar pattern along an imaginary plane parallel or substantially parallel to the first principal surface 21.

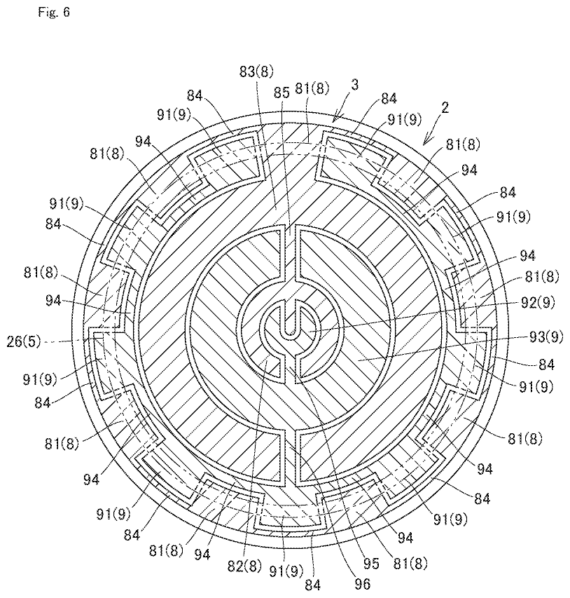

Reference is made to FIG. 6 to FIG. 9. The electrostatic chuck electrode 3 includes at least one positive electrode 8 and at least one negative electrode 9. In the at least one embodiment, the electrostatic chuck electrode 3 includes one positive electrode 8 and one negative electrode 9. A pair of the positive electrode 8 and the negative electrode 9 are provided between the first principal surface 21 and the second principal surface 22 so as to spread each in a planar pattern on the same imaginary plane while being separated from each other in a non-contact state.

The positive electrode 8 and the negative electrode 9 are each formed of a metal material such as molybdenum (Mo), tungsten (W), or ruthenium (Ru). The positive electrode 8 and the negative electrode 9 are each formed in a shape spreading in a planar pattern by forming the above-mentioned material into, for example, a thin sheet-like or net-like shape.

Although not shown, a power feeding terminal for a positive electrode that is to be electrically connected to the positive electrode 8 and a power feeding terminal for a negative electrode that is to be electrically connected to the negative electrode 9 are provided to the ceramic plate 2. The power feeding terminals are connected to a direct-current power supply via power feeding members, respectively. When a positive electrode of the direct-current power supply is electrically connected to the positive electrode 8, a positive voltage is applied thereto. When a negative electrode of the direct-current power supply is electrically connected to the negative electrode 9, a negative voltage is applied thereto. As a result, when a voltage is applied between the positive electrode 8 and the negative electrode 9, an attraction force resulting from a Coulomb force or a Johnsen-Rahbek force is generated on the first principal surface 21 of the ceramic plate 2, and the wafer 10 is attracted to the wafer supporting surface 23. When the application of the direct-current voltages to the positive electrode 8 and the negative electrode 9 is cancelled, the attraction of the wafer 10 to the wafer supporting surface 23 is cancelled.

### Description of Electrode Shapes of Positive Electrode and Negative Electrode

FIG. 6 shows a first example of electrode shapes of the positive electrode 8 and the negative electrode 9. In the following description of the electrode shapes, the terms “outer side” or “outside” and “inner side” or “inside” refer to an “outer side” or “outside” and an “inner side” or “inside” in a radial direction of the ceramic plate 2, respectively.

In the first example of the electrode shapes, the positive electrode 8 includes a plurality of first positive electrode portions 81, one second positive electrode portion 82, and one third positive electrode portion 83. When viewed in the direction orthogonal to the first principal surface 21, the plurality of first positive electrode portions 81, one third positive electrode portion 83, and one second positive electrode portion 82 are arranged in the stated order from the outer peripheral edge toward the center of the ceramic plate 2. Further, the negative electrode 9 includes a plurality of first negative electrode portions 91, one second negative electrode portion 92, and one third negative electrode portion 93. When viewed in the direction orthogonal to the first principal surface 21, the plurality of first negative electrode portions 91, one third negative electrode portion 93, and one second negative electrode portion 92 are arranged in the stated order from the outer peripheral edge toward the center of the ceramic plate 2.

The plurality of first positive electrode portions 81 and the plurality of first negative electrode portions 91 are positioned closest to the outer peripheral edge of the ceramic plate 2. The plurality of first positive electrode portions 81 and the plurality of first negative electrode portions 91 are arranged apart from each other in the circumferential direction of the ceramic plate 2 while being adjacent to the outer peripheral edge of the ceramic plate 2. That is, the plurality of first positive electrode portions 81 are arranged so that the first positive electrode portions 81 being adjacent to each other along the outer peripheral edge of the ceramic plate 2 leave a space for allowing one first negative electrode portion 91 to be placed therebetween. Further, the plurality of first negative electrode portions 91 are arranged so that the first negative electrode portions 91 being adjacent to each other along the outer peripheral edge of the ceramic plate 2 leave a space for allowing one first positive electrode portion 81 to be placed therebetween. As a result, the plurality of first positive electrode portions 81 and the plurality of first negative electrode portions 91 are alternately arranged in the circumferential direction of the ceramic plate 2.

When viewed in the direction orthogonal to the first principal surface 21, the plurality of first positive electrode portions 81 and the plurality of first negative electrode portions 91 are positioned below the first support wall 5 extending in the circumferential direction of the ceramic plate 2. That is, when viewed in the direction orthogonal to the first principal surface 21, the plurality of first positive electrode portions 81 and the plurality of first negative electrode portions 91 are alternately arranged in the circumferential direction of the ceramic plate 2 so that the plurality of first positive electrode portions 81 and the plurality of first negative electrode portions 91 overlap part of a ring-shaped region 26 of the first principal surface 21, on which the first support wall 5 is formed.

The first positive electrode portions 81 and the first negative electrode portions 91 are each formed in, when viewed in the direction orthogonal to the first principal surface 21, for example, a tapered shape with a width decreasing from the outer peripheral edge toward the center of the ceramic plate 2. The first positive electrode portions 81 and the first negative electrode portions 91 are each formed in, for example, a trapezoidal or fan-like shape. As a result, when the plurality of first positive electrode portions 81 and the plurality of first negative electrode portions 91 are alternately arranged in the circumferential direction of the ceramic plate 2, the plurality of first positive electrode portions 81 and the plurality of first negative electrode portions 91 are arranged in a dense state in which a gap between the first positive electrode portion 81 and the first negative electrode portion 91 that are adjacent to each other is small.

The third positive electrode portion 83 and the third negative electrode portion 93 are positioned farther away from the outer peripheral edge of the ceramic plate 2 than the plurality of first positive electrode portions 81 and the plurality of first negative electrode portions 91. The third positive electrode portion 83 is formed in, for example, a C-like shape formed by cutting away a part of an annulus when viewed in the direction orthogonal to the first principal surface 21. The third negative electrode portion 93 is formed in, for example, a C-like shape formed by cutting away a part of an annulus when viewed in the direction orthogonal to the first principal surface 21. The third negative electrode portion 93 is located inside of the third positive electrode portion 83, and the third positive electrode portion 83 is positioned closer to the outer peripheral edge of the ceramic plate 2 than the third negative electrode portion 93.

The second positive electrode portion 82 and the second negative electrode portion 92 are positioned farthest from the outer peripheral edge of the ceramic plate 2, and are positioned in the center of the ceramic plate 2. The power feeding terminal for a positive electrode is electrically connected to the second positive electrode portion 82, and the power feeding terminal for a negative electrode is electrically connected to the second negative electrode portion 92.

The second positive electrode portion 82 is formed in, for example, a C-like shape formed by cutting away a part of an annulus when viewed in the direction orthogonal to the first principal surface 21. The second negative electrode portion 92 is formed in, for example, a substantially circular shape when viewed in the direction orthogonal to the first principal surface 21. The second positive electrode portion 82 is located inside of the third negative electrode portion 93, and the second negative electrode portion 92 is located inside of the second positive electrode portion 82. The second positive electrode portion 83 is positioned closer to the outer peripheral edge of the ceramic plate 2 than the second negative electrode portion 93.

The third positive electrode portion 83 is connected to the second positive electrode portion 82 through a positive-electrode second connecting portion 85 having an elongated shape that passes through the third negative electrode portion 93. One of the plurality of first positive electrode portions 81 is connected to the third positive electrode portion 83. Two adjacent first positive electrode portions 81 among the plurality of first positive electrode portions 81 are connected to each other through a positive-electrode first connecting portion 84 having an elongated shape. The positive-electrode first connecting portion 84 passes, for example, on an outer side of the first negative electrode portions 91 and can connect two adjacent first positive electrode portions 81 to each other. As a result, the plurality of first positive electrode portions 81, one second positive electrode portion 82, and one third positive electrode portion 83 are connected into one continuous region.

Meanwhile, the third negative electrode portion 93 is connected to the second negative electrode portion 92 through a negative-electrode second connecting portion 95 having an elongated shape that passes through the second positive electrode portion 82. One of the plurality of first negative electrode portions 91 is connected to the third negative electrode portion 93 through a negative-electrode third connecting portion 96 having an elongated shape that passes through the third positive electrode portion 83. Two adjacent first negative electrode portions 91 among the plurality of first negative electrode portions 91 are connected to each other through a negative-electrode first connecting portion 94 having an elongated shape except for at one position. The negative-electrode first connecting portions 94 pass, for example, on an inner side of the first positive electrode portions 81 and can each connect two adjacent first negative electrode portions 91 to each other. As a result, the plurality of first negative electrode portions 91, one second negative electrode portion 92, and one third negative electrode portion 93 are connected into one continuous region.

As described above, in the at least one embodiment, the positive electrode 8 in which the plurality of first positive electrode portions 81, one second positive electrode portion 82, and one third positive electrode portion 83 are connected into one continuous region and the negative electrode 9 in which the plurality of first negative electrode portions 91, one second negative electrode portion 92, and one third negative electrode portion 93 are connected into one continuous region, the negative electrode 9 being in non-contact with the positive electrode 8, are formed by appropriately designing the electrode shapes. In this manner, the electrostatic chuck electrode 3 includes one positive electrode 8 and one negative electrode 9. At the same time, the plurality of first positive electrode portions 81 and the plurality of first negative electrode portions 91 can be alternately arranged in the circumferential direction of the ceramic plate 2 below the first support wall 5 when viewed in the direction orthogonal to the first principal surface 21.

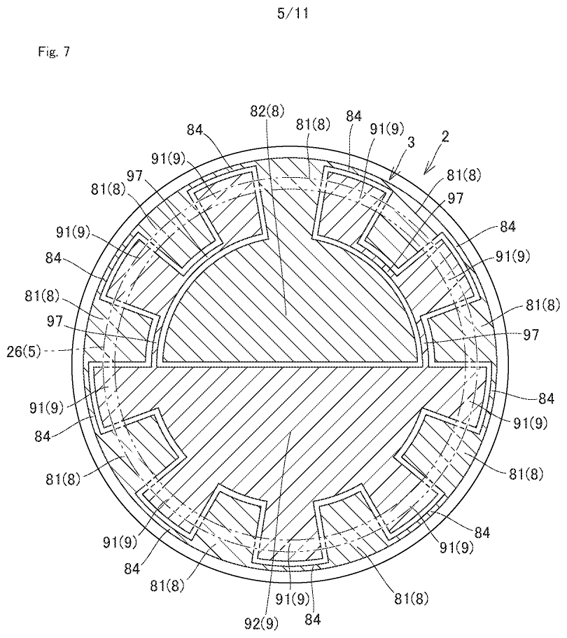

FIG. 7 shows a second example of the electrode shapes of the positive electrode 8 and the negative electrode 9. Also with the electrode shapes of the second example illustrated in FIG. 7, the electrostatic chuck electrode 3 includes one positive electrode 8 and one negative electrode 9. At the same time, the plurality of first positive electrode portions 81 and the plurality of first negative electrode portions 91 can be alternately arranged in the circumferential direction of the ceramic plate 2 below the first support wall 5 when viewed in the direction orthogonal to the first principal surface 21.

In the second example of the electrode shapes, the positive electrode 8 includes a plurality of first positive electrode portions 81 and one second positive electrode portion 82. When viewed in the direction orthogonal to the first principal surface 21, the plurality of first positive electrode portions 81 and one second positive electrode portion 82 are arranged in the stated order from the outer peripheral edge toward the center of the ceramic plate 2. Further, the negative electrode 9 includes a plurality of first negative electrode portions 91 and one second negative electrode portion 92. When viewed in the direction orthogonal to the first principal surface 21, the plurality of first negative electrode portions 91 and one second negative electrode portion 92 are arranged in the stated order from the outer peripheral edge toward the center of the ceramic plate 2.

The plurality of first positive electrode portions 81 and the plurality of first negative electrode portions 91 are positioned close to the outer peripheral edge of the ceramic plate 2. The plurality of first positive electrode portions 81 and the plurality of first negative electrode portions 91 are arranged apart from each other in the circumferential direction of the ceramic plate 2 while being adjacent to the outer peripheral edge of the ceramic plate 2. That is, the plurality of first positive electrode portions 81 are arranged so that the first positive electrode portions 81 being adjacent to each other along the outer peripheral edge of the ceramic plate 2 leave a space for allowing one first negative electrode portion 91 to be placed therebetween. Further, the plurality of first negative electrode portions 91 are arranged so that the first negative electrode portions 91 being adjacent to each other along the outer peripheral edge of the ceramic plate 2 leave a space for allowing one first positive electrode portion 81 to be placed therebetween. As a result, the plurality of first positive electrode portions 81 and the plurality of first negative electrode portions 91 are alternately arranged in the circumferential direction of the ceramic plate 2.

When viewed in the direction orthogonal to the first principal surface 21, the plurality of first positive electrode portions 81 and the plurality of first negative electrode portions 91 are positioned below the first support wall 5 extending in the circumferential direction of the ceramic plate 2. That is, when viewed in the direction orthogonal to the first principal surface 21, the plurality of first positive electrode portions 81 and the plurality of first negative electrode portions 91 are alternately arranged in the circumferential direction of the ceramic plate 2 so that the plurality of first positive electrode portions 81 and the plurality of first negative electrode portions 91 overlap part of a ring-shaped region 26 of the first principal surface 21, on which the first support wall 5 is formed.

The first positive electrode portions 81 and the first negative electrode portions 91 are each formed in, when viewed in the direction orthogonal to the first principal surface 21, for example, a tapered shape with a width decreasing from the outer peripheral edge toward the center of the ceramic plate 2. The first positive electrode portions 81 and the first negative electrode portions 91 are each formed in, for example, a trapezoidal or fan-like shape. As a result, when the plurality of first positive electrode portions 81 and the plurality of first negative electrode portions 91 are alternately arranged in the circumferential direction of the ceramic plate 2, the plurality of first positive electrode portions 81 and the plurality of first negative electrode portions 91 are arranged in a dense state in which a gap between the first positive electrode portion 81 and the first negative electrode portion 91 that are adjacent to each other is small.

The second positive electrode portion 82 and the second negative electrode portion 92 are positioned in the center of the ceramic plate 2. The power feeding terminal for a positive electrode is electrically connected to the second positive electrode portion 82, and the power feeding terminal for a negative electrode is electrically connected to the second negative electrode portion 92.

The second positive electrode portion 82 and the second negative electrode portion 92 are each formed in, for example, a semi-circular shape when viewed in the direction orthogonal to the first principal surface 21. The second positive electrode portion 82 and the second negative electrode portion 92 are arranged such that portions corresponding to their diameters face each other while being apart from each other to form a single circle.

One of the plurality of first positive electrode portions 81 is connected to the second positive electrode portion 82. Two adjacent first positive electrode portions 81 among the plurality of first positive electrode portions 81 are connected to each other through a positive-electrode first connecting portion 84 having an elongated shape. The positive-electrode first connecting portion 84 passes, for example, on an outer side of the first negative electrode portions 91 and can connect two adjacent first positive electrode portions 81 to each other. As a result, the plurality of first positive electrode portions 81 and one second positive electrode portion 82 are connected into one continuous region.

Meanwhile, five first negative electrode portions 91 among the plurality of first negative electrode portions 91 are connected to the second negative electrode portion 92. The remaining first negative electrode portions 91 among the plurality of first negative electrode portions 91 are connected to the second negative electrode portion 92 through negative-electrode fourth connecting portions 97 each having an elongated shape that extend from the second negative electrode portion 92 and pass on an inner side of the first positive electrode portions 81. As a result, the plurality of first negative electrode portions 91 and one second negative electrode portion 92 are connected into one continuous region.

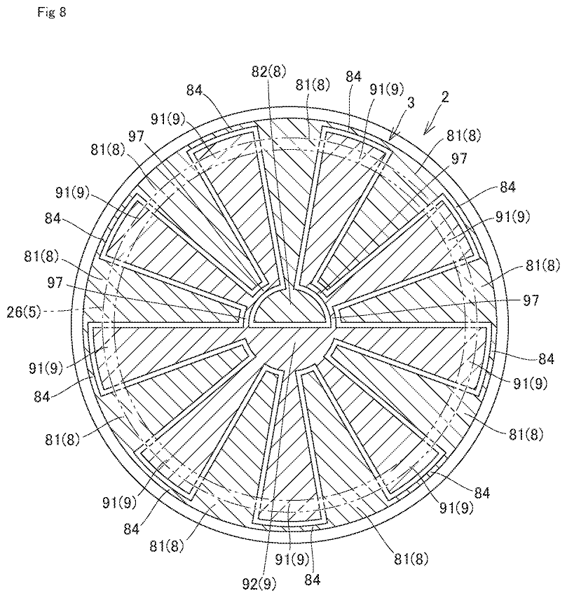

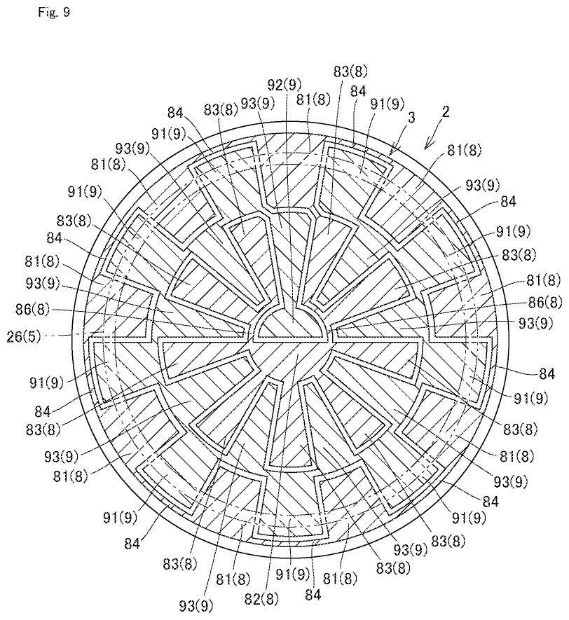

FIG. 8 shows a third example of the electrode shapes of the positive electrode 8 and the negative electrode 9. Also with the electrode shapes of the third example illustrated in FIG. 8, the electrostatic chuck electrode 3 includes one positive electrode 8 and one negative electrode 9. At the same time, the plurality of first positive electrode portions 81 and the plurality of first negative electrode portions 91 can be alternately arranged in the circumferential direction of the ceramic plate 2 below the first support wall 5 when viewed in the direction orthogonal to the first principal surface 21.

The third example of the electrode shapes is a modification example of the above-mentioned second example of the electrode shapes illustrated in FIG. 7, and only differences therebetween are described here. In the third example of the electrode shapes, the second positive electrode portion 82 and the second negative electrode portion 92 each have a semi-circular shape with a small diameter. The plurality of first positive electrode portions 81 and the plurality of first negative electrode portions 91 extend correspondingly longer in the radial direction. That is, the plurality of first positive electrode portions 81 and the plurality of first negative electrode portions 91 extend between the vicinity of the outer peripheral edge of the ceramic plate 2 and the vicinity of the center thereof.

FIG. 9 shows a fourth example of the electrode shapes of the positive electrode 8 and the negative electrode 9. Also with the electrode shapes of the fourth example illustrated in FIG. 9, the electrostatic chuck electrode 3 includes one positive electrode 8 and one negative electrode 9. At the same time, the plurality of first positive electrode portions 81 and the plurality of first negative electrode portions 91 can be alternately arranged in the circumferential direction of the ceramic plate 2 below the first support wall 5 when viewed in the direction orthogonal to the first principal surface 21.

In the fourth example of the electrode shapes, the positive electrode 8 includes a plurality of first positive electrode portions 81, one second positive electrode portion 82, and a plurality of third positive electrode portions 83. When viewed in the direction orthogonal to the first principal surface 21, the plurality of first positive electrode portions 81, the plurality of third positive electrode portions 83, and one second positive electrode portion 82 are arranged in the stated order from the outer peripheral edge toward the center of the ceramic plate 2. Further, the negative electrode 9 includes a plurality of first negative electrode portions 91, one second negative electrode portion 92, and a plurality of third negative electrode portions 93. When viewed in the direction orthogonal to the first principal surface 21, the plurality of first negative electrode portions 91, the plurality of third negative electrode portions 93, and one second negative electrode portion 92 are arranged in the stated order from the outer peripheral edge toward the center of the ceramic plate 2.

The plurality of first positive electrode portions 81 and the plurality of first negative electrode portions 91 are positioned closest to the outer peripheral edge of the ceramic plate 2. The plurality of first positive electrode portions 81 and the plurality of first negative electrode portions 91 are arranged apart from each other in the circumferential direction of the ceramic plate 2 while being adjacent to the outer peripheral edge of the ceramic plate 2. That is, the plurality of first positive electrode portions 81 are arranged so that the first positive electrode portions 81 being adjacent to each other along the outer peripheral edge of the ceramic plate 2 leave a space for allowing one first negative electrode portion 91 to be placed therebetween. Further, the plurality of first negative electrode portions 91 are arranged so that the first negative electrode portions 91 being adjacent to each other along the outer peripheral edge of the ceramic plate 2 leave a space for allowing one first positive electrode portion 81 to be placed therebetween. As a result, the plurality of first positive electrode portions 81 and the plurality of first negative electrode portions 91 are alternately arranged in the circumferential direction of the ceramic plate 2.

When viewed in the direction orthogonal to the first principal surface 21, the plurality of first positive electrode portions 81 and the plurality of first negative electrode portions 91 are positioned below the first support wall 5 extending in the circumferential direction of the ceramic plate 2. That is, when viewed in the direction orthogonal to the first principal surface 21, the plurality of first positive electrode portions 81 and the plurality of first negative electrode portions 91 are alternately arranged in the circumferential direction of the ceramic plate 2 so that the plurality of first positive electrode portions 81 and the plurality of first negative electrode portions 91 overlap part of a ring-shaped region 26 of the first principal surface 21, on which the first support wall 5 is formed.

The first positive electrode portions 81 and the first negative electrode portions 91 are each formed in, when viewed in the direction orthogonal to the first principal surface 21, for example, a tapered shape with a width decreasing from the outer peripheral edge toward the center of the ceramic plate 2. The first positive electrode portions 81 and the first negative electrode portions 91 are each formed in, for example, a trapezoidal or fan-like shape. As a result, when the plurality of first positive electrode portions 81 and the plurality of first negative electrode portions 91 are alternately arranged in the circumferential direction of the ceramic plate 2, the plurality of first positive electrode portions 81 and the plurality of first negative electrode portions 91 are arranged in a dense state in which a gap between the first positive electrode portion 81 and the first negative electrode portion 91 that are adjacent to each other is small.

The plurality of third positive electrode portions 83 and the plurality of third negative electrode portions 93 are positioned farther from the outer peripheral edge of the ceramic plate 2 than the plurality of first positive electrode portions 81 and the plurality of first negative electrode portions 91. The plurality of first positive electrode portions 81 and the plurality of first negative electrode portions 91 are arranged apart from each other in the circumferential direction of the ceramic plate 2 while being adjacent to the plurality of third negative electrode portions 93 and the plurality of third positive electrode portions 83, respectively. That is, the plurality of third positive electrode portions 83 are arranged in the circumferential direction of the ceramic plate 2 while leaving a space for allowing one third negative electrode portion 93 to be placed between adjacent third positive electrode portions 83 among the plurality of third positive electrode portions 83. Further, the plurality of third negative electrode portions 93 are arranged in the circumferential direction of the ceramic plate 2 while leaving a space for allowing one third positive electrode portion 83 to be placed between adjacent third negative electrode portions 93 among the plurality of third negative electrode portions 93. As a result, the plurality of third positive electrode portions 83 and the plurality of third negative electrode portions 93 are alternately arranged in the circumferential direction of the ceramic plate 2. The plurality of third positive electrode portions 83 and the plurality of third negative electrode portions 93 are arranged so that the third negative electrode portions 93 are positioned on an inner side of the first positive electrode portions 81 and the third positive electrode portions 83 are positioned on an inner side of the first negative electrode portions 91.

The third positive electrode portions 83 and the third negative electrode portions 93 are each formed in, when viewed in the direction orthogonal to the first principal surface 21, for example, a tapered shape with a width decreasing from the outer peripheral edge toward the center of the ceramic plate 2. The third positive electrode portions 83 and the third negative electrode portions 93 are each formed in, for example, a trapezoidal or fan-like shape. As a result, when the plurality of third positive electrode portions 83 and the plurality of third negative electrode portions 93 are alternately arranged in the circumferential direction of the ceramic plate 2, the plurality of third positive electrode portions 83 and the plurality of third negative electrode portions 93 are arranged in a dense state in which a gap between the third positive electrode portion 83 and the third negative electrode portion 93 that are adjacent to each other is small.

The second positive electrode portion 82 and the second negative electrode portion 92 are positioned farthest from the outer peripheral edge of the ceramic plate 2, and are positioned in the center of the ceramic plate 2. The power feeding terminal for a positive electrode is electrically connected to the second positive electrode portion 82, and the power feeding terminal for a negative electrode is electrically connected to the second negative electrode portion 92.

The second positive electrode portion 82 and the second negative electrode portion 92 are each formed in, for example, a semi-circular shape when viewed in the direction orthogonal to the first principal surface 21. The second positive electrode portion 82 and the second negative electrode portion 92 are arranged such that portions corresponding to their diameters face each other while being apart from each other to form a single circle.

Five third positive electrode portions 83 among the plurality of third positive electrode portions 83 are connected to the second positive electrode portion 82. The remaining third positive electrode portions 83 among the plurality of third positive electrode portions 83 are connected to the second positive electrode portion 82 through positive-electrode third connecting portions 86 each having an elongated shape that extend from the second positive electrode portion 82 and pass on an inner side of the third negative electrode portions 93. One of the plurality of first positive electrode portions 81 is connected to one of the plurality of third positive electrode portions 83. Two adjacent first positive electrode portions 81 among the plurality of first positive electrode portions 81 are connected to each other through a positive-electrode first connecting portion 84 having an elongated shape. The positive-electrode first connecting portion 84 passes, for example, on an outer side of the first negative electrode portions 91 and can connect two adjacent first positive electrode portions 81 to each other. As a result, the plurality of first positive electrode portions 81, one second positive electrode portion 82, and the plurality of third positive electrode portions 83 are connected into one continuous region.

Meanwhile, one of the plurality of third negative electrode portions 93 is connected to the second negative electrode portion 92. One of the plurality of first negative electrode portions 91 is connected to the one third negative electrode portion 93. The third negative electrode portion 93 that is adjacent to the one third negative electrode portion 93 is connected to the one first negative electrode portion 91. The connection between the third negative electrode portion 93 and the first negative electrode portion 91 is repeated in the circumferential direction of the ceramic plate 2 to thereby achieve the connection between the plurality of third negative electrode portions 93 and the plurality of first negative electrode portions 91. As a result, the plurality of first negative electrode portions 91, one second negative electrode portion 92, and the plurality of third negative electrode portions 93 are connected into one continuous region.

The above-mentioned electrode shapes of the positive electrodes 8 and the negative electrodes 9 illustrated in FIG. 6 to FIG. 9 are all exemplary. The electrode shapes of the positive electrode 8 and the negative electrode 9 are not limited to particular shapes as long as the electrostatic chuck electrode 3 includes one positive electrode 8 and one negative electrode 9, and the plurality of first positive electrode portions 81 and the plurality of first negative electrode portions 91 are alternately arranged in the circumferential direction of the ceramic plate 2 below the first support wall 5 when viewed in the direction orthogonal to the first principal surface 21.

### Description of Resistance Heating Element

Reference is made to FIG. 2. The resistance heating element 4 generates heat through energization. The resistance heating element 4 can be formed of a metal material such as molybdenum (Mo), tungsten (W), or niobium (Nb), or a mixed material of the metal material and ceramic. As the ceramic, the same material as the ceramic contained as a main component in the ceramic plate 2 is used.

The resistance heating element 4 is provided between the first principal surface 21 and the second principal surface 22 of the ceramic plate 2 so as to spread in a planar pattern along an imaginary plane parallel or substantially parallel to the first principal surface 21. The resistance heating element 4 is provided between the first principal surface 21 and the second principal surface 22 of the ceramic plate 2 so as to spread in a planar pattern by arranging, for example, a coil or a planar meandering element wire, which is formed using one of the above-mentioned materials, or a sheet-shaped printed electrode in a predetermined wiring pattern with a single continuous line over a substantially entire area of the ceramic plate 2 from the center to the outer peripheral edge thereof.

Although not shown, power feeding terminals, which are to be electrically connected to both ends of the resistance heating element 4, are provided to the ceramic plate 2. The pair of power feeding terminals are connected to a direct-current power supply via power feeding members. When the resistance heating element 4 is energized by the direct-current power supply and generates heat, the entirety of the ceramic plate 2 is heated, and the wafer 10 is heated via the wafer supporting surface 23 being heated.

The resistance heating element 4 can be formed in a split manner as a first resistance heating element and a second resistance heating element. When viewed in the direction orthogonal to the first principal surface 21, the first resistance heating element is arranged at a position closer to the center of the ceramic plate 2, and the second resistance heating element is arranged at a position closer to the outer peripheral edge of the ceramic plate 2. In this case, power feeding members are connected to a pair of power feeding terminals that are electrically connected to both ends of the first resistance heating element, respectively, and power feeding members are connected to a pair of power feeding terminals that are electrically connected to both ends of the second resistance heating element, respectively.

### Description of Actions and Effects of Susceptor

With the susceptor 1 according to the at least one embodiment, the plurality of first positive electrode portions 81 and the plurality of first negative electrode portions 91 are alternately arranged in the circumferential direction of the ceramic plate 2 below the first support wall 5, on which the wafer 10 is to be placed, inside the ceramic plate 2. Accordingly, when a voltage is applied between the positive electrode 8 and the negative electrode 9, portions with a high attraction force and portions with a low attraction force are alternately formed in a well-balanced manner in the first support wall 5. Thus, with the susceptor 1 according to the at least one embodiment, non-uniformity in the attraction of the wafer 10 caused by the first support wall 5 is suppressed. As a result, the wafer 10 can be stably held on the first principal surface 21.

Further, with the susceptor 1 according to the at least one embodiment, only one positive electrode 8 and only one negative electrode 9 are built in the ceramic plate 2 as the electrostatic chuck electrode 3. The plurality of first positive electrode portions 81 and the plurality of first negative electrode portions 91 are alternately arranged in the circumferential direction of the ceramic plate 2 below the first support wall 5 by appropriately designing the electrode shapes of the positive electrode 8 and the negative electrode 9. Accordingly, only one power feeding terminal for a positive electrode and only one power feeding terminal for a negative electrode are required to be provided to the ceramic plate 2. Thus, the structure of the ceramic plate 2 can be simplified. Further, the resistance heating element 4, which is built in the ceramic plate 2, is required to be arranged while avoiding the power feeding terminals. One positive electrode 8 and one negative electrode 9 are built in the ceramic plate 2, and thus one power feeding terminal for a positive electrode and one power feeding terminal for a negative electrode are only required to be provided to the ceramic plate 2. Thus, cool spots, which may be formed in the ceramic plate 2, can be reduced by arranging the resistance heating element 4 in a wiring pattern while avoiding the power feeding terminals. As a result, when the ceramic plate 2 is heated with the resistance heating element 4, non-uniformity in temperature is less liable to occur in the ceramic plate 2. Thus, in the susceptor 1 of the at least one embodiment, thermal uniformity of the ceramic plate 2 can be improved.

Further, with the susceptor 1 according to the at least one embodiment, when the plurality of first positive electrode portions 81 and the plurality of first negative electrode portions 91 or the plurality of third positive electrode portions 83 and the plurality of third negative electrode portions 93 are alternately arranged in the circumferential direction of the ceramic plate 2 inside the ceramic plate 2, not only under the first support wall 5 but also on the inner side of the first support wall 5 as illustrated in FIG. 8 or FIG. 9, the application of a voltage between the positive electrode 8 and the negative electrode 9 forms portions with a high attraction force and portions with a low attraction force that are alternately arranged in a well-balanced manner over substantially the entire wafer supporting surface 23. Thus, according to the example illustrated in FIG. 8 or the example illustrated in FIG. 9, non-uniformity in the attraction of the wafer 10 to the wafer supporting surface 23 is suppressed, and hence the wafer 10 can be more stably held on the first principal surface 21.

Further, with the susceptor 1 according to the at least one embodiment, the ceramic plate 2 can be heated with the resistance heating element 4 built in the ceramic plate 2, and the wafer 10 can be heated via the wafer supporting surface 23. At this time, the wafer 10 is attracted to the wafer supporting surface 23 under a state in which non-uniformity in the attraction force is suppressed. Thus, the wafer 10 can be uniformly heated.

Further, with the susceptor 1 according to the at least one embodiment, the wafer 10 is supported on the wafer supporting surface 23 while being in contact not only with the distal end surface of the first support wall 5 but also with the distal end surfaces of the plurality of support protrusions 6. Thus, the wafer 10 is more stably supported on the first principal surface 21. Further, when portions with a high attraction force and portions with a low attraction force are formed alternately in a well-balanced manner over substantially the entire wafer supporting surface 23 as in the example illustrated in FIG. 8 or the example illustrated in FIG. 9, non-uniformity in the attraction of the wafer 10 caused by the plurality of support protrusions 6 is suppressed. Accordingly, the wafer 10 can be stably held on the first principal surface 21.

Further, with the susceptor 1 according to the at least one embodiment, the proportion of the area of the first support wall 5 that is to be in contact with the wafer 10 in the total area of the portions of the ceramic plate 2 that are to be in contact with the wafer 10 is 40% or more. As described above, among the above-mentioned portions, the first support wall 5 is a main portion being in contact with the wafer 10, and hence the wafer 10 can be more stably held on the first principal surface 21.

Further, with the susceptor 1 according to the at least one embodiment, when the wafer 10 is placed on the first support wall 5, the space 13 surrounded by the first support wall 5 is defined between the wafer 10 and the ceramic plate 2. This space 13 is sealed. Thus, the wafer 10 can be efficiently and uniformly heated by supplying, for example, a gas for enabling efficient thermal conduction between the wafer 10 and the ceramic plate 2 into the space 13.

### Description of Modification Examples

The description has been given above on the susceptor 1 according to the at least one embodiment of the present disclosure. The at least one embodiment can be modified in various ways without departing from the gist of the present disclosure. For example, the at least one embodiment can be modified in manners described below. The modifications described below may be appropriately combined.

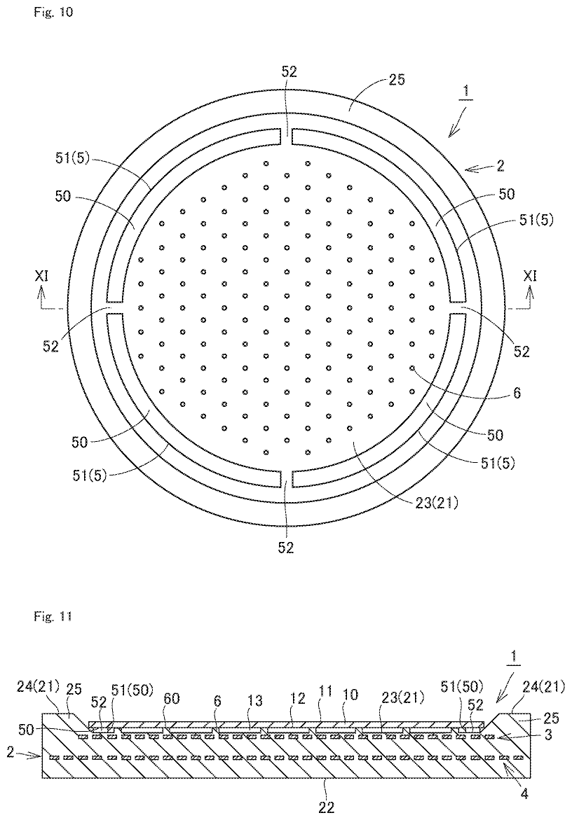

As one modification example, the first support wall 5 of the susceptor 1 may be formed from a plurality of ridge portions 51 that are arranged apart from each other in the circumferential direction of the ceramic plate 2 as illustrated in FIG. 10 and FIG. 11. In the example illustrated in FIG. 10 and FIG. 11, the first support wall 5 is formed from four ridge portions 51, and each of the ridge portions 51 is formed from an arc-like quarter-circle projection. Four ridge portions 51 are arranged so as to form an annulus with voids 52 between adjacent ridge portions 51.

Also in the example illustrated in FIG. 10 and FIG. 11, the wafer 10 can be uniformly heated by supplying, for example, a gas for enabling efficient thermal conduction between the wafer 10 and the ceramic plate 2 into the space 13 surrounded by the first support wall 5, which is defined between the wafer 10 and the ceramic plate 2. Further, when, for example, a film forming process is performed on the first principal surface 11 of the wafer 10, formation of an abnormal film on the outer peripheral edge of the second principal surface 12 of the wafer 10 can be suppressed by discharging the gas from the space 13 to the outside of the first support wall 5 through the voids 52 between adjacent ridge portions 51.

As another modification example, the plurality of support protrusions 6 may be omitted and only the first support wall 5 may be formed on the ceramic plate 2 of the susceptor 1.

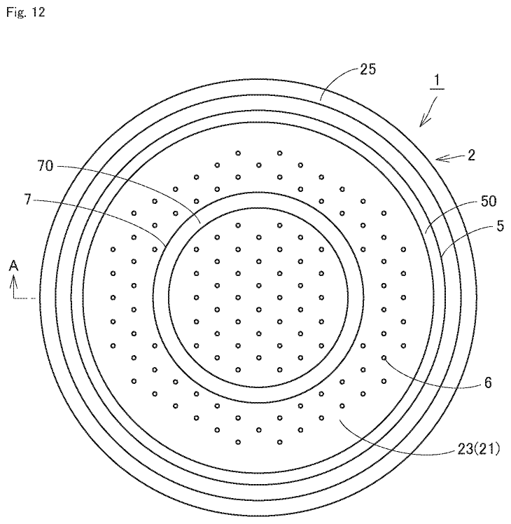

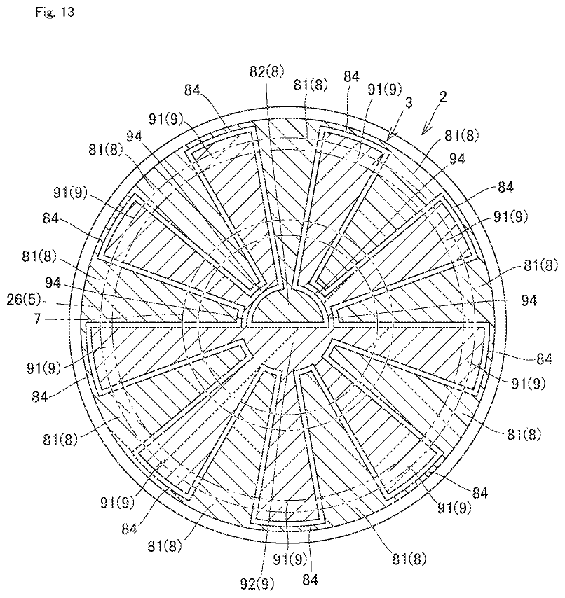

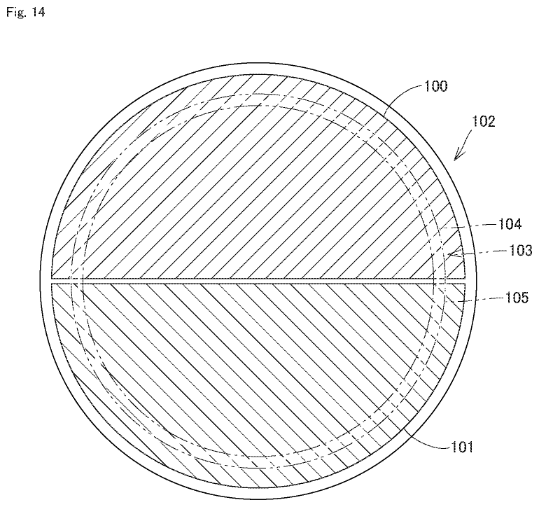

As still another modification example, at least one second support wall 7 protruding from the wafer supporting surface 23 of the first principal surface 21 may be formed on the ceramic plate 2 of the susceptor 1 in place of or in addition to the plurality of support protrusions 6, as illustrated in FIG. 12 and FIG. 13. The second support wall 7 may be formed on a region of the wafer supporting surface 23 that is surrounded by the first support wall 5. The second support wall 7 can be formed of a ring-shaped protrusion, for example, an annular protrusion extending over the entire circumference in the circumferential direction of the ceramic plate 2.

A sectional shape of the second support wall 7 perpendicular to the wafer supporting surface 23 is, for example, rectangular or trapezoidal. An end surface (distal end surface) 70 of the second support wall 7, which protrudes from the wafer supporting surface 23, may be formed as a flat or substantially flat surface. A height of the second support wall 7, that is, a length by which the second support wall 7 protrudes from the wafer supporting surface 23 (a vertical distance between the distal end surface 70 of the second support wall 7 and the wafer supporting surface 23) is from about several μm to about several hundred μm. Further, a width of the second support wall 7, that is, a distance between an inner peripheral surface and an outer peripheral surface of the second support wall 7 is from about 0.5 mm to about 50 mm.

The distal end surface 70, which is the distal end of the second support wall 7, is positioned at the same height or substantially the same height in the thickness direction of the ceramic plate 2 as a height at which the distal end surface 50, which is the distal end of the first support wall 5, is positioned. In this modification example, a length by which the first support wall 5 protrudes from the wafer supporting surface 23, which defines the height of the first support wall 5, and a length by which the second support wall 7 protrudes from the wafer supporting surface 23, which defines the height of the second support wall 7, are the same or substantially the same.

When the wafer 10 is to be supported on the wafer supporting surface 23 of the ceramic plate 2, the wafer 10 is placed in contact not only with the distal end surface 50 of the first support wall 5 but also with the distal end surface 70 of the second support wall 7. The distal end surface 70 of the second support wall 7 is in contact with the second principal surface 12 of the wafer 10, and the wafer 10 is supported by the second support wall 7 from below.

In this modification example, the portions of the ceramic plate 2 that are to be in contact with the wafer 10 are a set of the distal end surface 50 of the first support wall 5 and the distal end surface 70 of the second support wall 7 or a set of the distal end surface 50 of the first support wall 5, the distal end surfaces 60 of the plurality of support protrusions 6, and the distal end surface 70 of the second support wall 7. Also in this modification example, the proportion of the area of the first support wall 5 in the total area of the portions to be in contact with the wafer 10 is preferably 40% or more. When only the first support wall 5 and the second support wall 7 are formed on the wafer supporting surface 23, the proportion is more preferably 50% or more, still more preferably 60% or more. Further, when the first support wall 5, the plurality of support protrusions 6, and the second support wall 7 are formed on the wafer supporting surface 23, the proportion is more preferably 45% or more, still more preferably 50% or more.

In the example illustrated in FIG. 12 and FIG. 13, when the wafer 10 is placed on the first support wall 5 and the second support wall 7, a first space surrounded by the second support wall 7 and a second space surrounded by the first support wall 5 on an outer side of the second support wall 7 are defined between the wafer 10 and the ceramic plate 2. Thermal conduction from the ceramic plate 2 to the wafer 10 can be adjusted by, for example, supplying gases having different thermal conductivities into the first space and the second space, respectively. Further, the wafer 10 is supported on the first principal surface 21 while being placed in contact not only with the distal end surface of the first support wall 5 but also with the distal end surface of the second support wall 7. Thus, the wafer 10 is more stably supported on the first principal surface 21. Further, when portions with a high attraction force and portions with a low attraction force are alternately formed in a well-balanced manner over substantially the entire first principal surface 21 by alternately arranging the plurality of first positive electrode portions 81, the plurality of first negative electrode portions 91, and the like in the circumferential direction of the ceramic plate 2 and on the inner side of the first support wall 5 as illustrated in FIG. 13, non-uniformity in the attraction of the wafer 10 caused by the second support wall 7 is suppressed. Accordingly, the wafer 10 can be stably held on the first principal surface 21.

As still another modification example, a tubular shaft formed of ceramic may be bonded to the second principal surface 22 of the ceramic plate 2. Alternatively, a cooling plate including a refrigerant flow path therein may be bonded to the second principal surface 22 of the ceramic plate 2.

It is to be understood that the at least one embodiment disclosed herein is merely an example in all aspects and in no way intended to limit the present invention in any aspect. The scope of the present invention is defined by the appended claims and not by the above description, and it is intended that the present invention encompasses all modifications made within the scope and spirit equivalent to those of the appended claims.

1. A susceptor, comprising:
a ceramic plate having a first principal surface and a second principal surface being a pair of principal surfaces which are positioned apart from each other in a thickness direction of the ceramic plate,
wherein a first support wall which extends in a circumferential direction of the ceramic plate and on which a wafer is to be placed is formed on the first principal surface of the ceramic plate,
wherein an electrostatic chuck electrode configured to attract the wafer is built in the ceramic plate,
wherein the electrostatic chuck electrode includes:
a single positive electrode to which a positive voltage is to be applied; and
a single negative electrode to which a negative voltage is to be applied,
wherein the positive electrode includes:
a plurality of first positive electrode portions which overlap part of a ring-shaped region of the first principal surface when viewed in a direction orthogonal to the first principal surface, the first support wall being formed on the ring-shaped region, and are arranged apart from each other in the circumferential direction of the ceramic plate; and
a second positive electrode portion which is continuous with the plurality of first positive electrode portions, and to which a power feeding terminal for a positive electrode is to be electrically connected,
wherein the negative electrode includes:
a plurality of first negative electrode portions which overlap part of the ring-shaped region when viewed in the direction orthogonal to the first principal surface, and are arranged apart from each other in the circumferential direction of the ceramic plate; and
a second negative electrode portion which is continuous with the plurality of first negative electrode portions, and to which a power feeding terminal for a negative electrode is to be electrically connected, and
wherein the plurality of first positive electrode portions and the plurality of first negative electrode portions are alternately arranged in the circumferential direction of the ceramic plate.

2. The susceptor according to claim 1, wherein, when viewed in the direction orthogonal to the first principal surface, the second positive electrode portion and the second negative electrode portion are arranged in a center of the ceramic plate, one of the plurality of first positive electrode portions or the plurality of first negative electrode portions extend from an outer peripheral edge of the ceramic plate toward the center of the ceramic plate, and another one of the plurality of first positive electrode portions or the plurality of first negative electrode portions extend from the center of the ceramic plate toward the outer peripheral edge of the ceramic plate.

3. The susceptor according to claim 1,
wherein, when viewed in the direction orthogonal to the first principal surface, the second positive electrode portion and the second negative electrode portion are arranged in a center of the ceramic plate,
wherein the positive electrode includes a plurality of third positive electrode portions which are arranged between the plurality of first positive electrode portions and the second positive electrode portion so as to be apart from each other in the circumferential direction of the ceramic plate, the plurality of third positive electrode portions being continuous with the plurality of first positive electrode portions and the second positive electrode portion, and
wherein the negative electrode includes a plurality of third negative electrode portions which are arranged alternately with the plurality of third positive electrode portions in the circumferential direction of the ceramic plate between the plurality of first negative electrode portions and the second negative electrode portion, the plurality of third negative electrode portions being continuous with the plurality of first negative electrode portions and the second negative electrode portion.

4. The susceptor according to claim 1, wherein a resistance heating element configured to generate heat through energization is built in the ceramic plate.

5. The susceptor according to claim 2,
wherein at least one of a set of a plurality of support protrusions or at least one second support wall extending in the circumferential direction of the ceramic plate is formed on a region of the first principal surface of the ceramic plate, the region being surrounded by the first support wall, and
wherein distal ends of the plurality of support protrusions and a distal end of the second support wall are positioned at the same height in the thickness direction of the ceramic plate as a height at which a distal end of the first support wall is positioned.

6. The susceptor according to claim 3,
wherein at least one of a set of a plurality of support protrusions or at least one second support wall extending in the circumferential direction of the ceramic plate is formed on a region of the first principal surface of the ceramic plate, the region being surrounded by the first support wall, and
wherein distal ends of the plurality of support protrusions and a distal end of the second support wall are positioned at the same height in the thickness direction of the ceramic plate as a height at which a distal end of the first support wall is positioned.

7. The susceptor according to claim 5, wherein a proportion of an area of the first support wall that is to be in contact with the wafer in a total area of portions of the ceramic plate that are to be in contact with the wafer is 40% or more.

8. The susceptor according to claim 6, wherein a proportion of an area of the first support wall that is to be in contact with the wafer in a total area of portions of the ceramic plate that are to be in contact with the wafer is 40% or more.

9. The susceptor according to claim 1, wherein the first support wall is formed in a ring shape so as to extend over an entire circumference in the circumferential direction of the ceramic plate.

10. The susceptor according to claim 1, wherein the first support wall is formed from a plurality of ridge portions which extend in the circumferential direction of the ceramic plate and are arranged apart from each other in the circumferential direction of the ceramic plate.

11. The susceptor according to claim 1,
wherein the wafer is a semiconductor substrate, and
wherein the susceptor is used for attraction of the semiconductor substrate.
